(19) United States
(12) Patent Application Publication
(10) Pub. No.: US 2022/0337028 A1
(43) Pub. Date: Oct. 20, 2022

(54) LIGHT-EMITTING DEVICE AND MEASUREMENT DEVICE

(71) Applicant: FUJIFILM Business Innovation Corp., Tokyo (JP)

(72) Inventors: Takashi KONDO, Kanagawa (JP); Seiji ONO, Kanagawa (JP); Daisuke IGUCHI, Kanagawa (JP); Tomoaki SAKITA, Kanagawa (JP)

(73) Assignee: FUJIFILM Business Innovation Corp., Tokyo (JP)

(21) Appl. No.: 17/405,657

(22) Filed: Aug. 18, 2021

(30) Foreign Application Priority Data
Apr. 14, 2021 (JP) 2021-068713

(51) Int. Cl. H01S 5/042; H01S 5/42; G01B 11/24

(52) U.S. Cl. CPC H01S 5/042; H01S 5/423; G01B 11/24

(57) ABSTRACT

A light-emitting device includes: plural light-emitting units; a driving unit that drives the light-emitting units by supplying a current to the light-emitting units; and a switching unit that is provided on a side opposite to a side where the driving unit is provided relative to the plural light-emitting units and switches light emission of the plural light-emitting units.

### CROSS-REFERENCE TO RELATED APPLICATIONS

This application is based on and claims priority under 35 USC 119 from Japanese Patent Application No. 2021-068713 filed Apr. 14, 2021.

### BACKGROUND

### (i) Technical Field

The present disclosure relates to a light-emitting device and a measurement device.

### (ii) Related Art

Japanese Unexamined Patent Application Publication No. 01-238962 describes a light-emitting element array in which a large number of light-emitting elements whose threshold voltage or threshold current is externally controllable by light are aligned one-dimensionally, two-dimensionally, or three-dimensionally, at least part of light generated from each of the light-emitting elements enters another light-emitting element close to the light-emitting element, and a clock line that externally applies a voltage or a current to each of the light-emitting elements.

Japanese Unexamined Patent Application Publication No. 2001-308385 describes a self-scanning light-emitting device in which a light-emitting element of pnpnpn six-layer semiconductor structure is provided, a p-type first layer and an n-type sixth layer on both ends and a p-type third layer and an n-type fourth layer in the center are provided with an electrode, pn layers are given a light-emitting diode function, and pnpn four layers are given a thyristor function.

Japanese Unexamined Patent Application Publication No. 2009-286048 describes a self-scanning light source head including a substrate, surface-emitting semiconductor lasers provided in an array on the substrate, and thyristors that are aligned on the substrate and serve as switch elements for selectively turning on and off light emission of the surface-emitting semiconductor lasers.

### SUMMARY

In a method for measuring a three-dimensional shape of an object to be measured by irradiating the object to be measured with light from a light-emitting device and receiving the light reflected by the object to be measured, it is required that a rise time of light pulse with which the object to be measured is irradiated be short. To achieve this, it is desirable to shorten a distance between light-emitting units and a driving unit that supplies a current for light emission in a light-emitting device and thereby reduce inductance.

Aspects of non-limiting embodiments of the present disclosure relate to a light-emitting device etc. in which light emission of plural light-emitting units is switched and a distance between the light-emitting units and a driving unit can be shortened as compared with a case where a switching unit that switches the light-emitting units is provided between the light-emitting units and the driving unit.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light-emitting device including: plural light-emitting units; a driving unit that drives the light-emitting units by supplying a current to the light-emitting units; and a switching unit that is provided on a side opposite to a side where the driving unit is provided relative to the plural light-emitting units and switches light emission of the plural light-emitting units.

### BRIEF DESCRIPTION OF THE DRAWINGS

An exemplary embodiment of the present disclosure will be described in detail based on the following figures, wherein:

FIG. 1 illustrates an example of an information processing apparatus;

FIG. 2 is a block diagram for explaining a configuration of the information processing apparatus;

FIG. 3 is a perspective view for explaining a state where a light source of a light-emitting device irradiates an irradiation region in a divided manner;

FIG. 4 is a view for explaining the light source of the light-emitting device;

FIG. 5 is a view for explaining a way in which the light source and a driving unit are disposed in the light-emitting device;

FIG. 6 illustrates an equivalent circuit of the light-emitting device to which the present exemplary embodiment is applied;

FIG. 7 is a timing diagram for explaining operation of the light-emitting device;

FIG. 8 is an enlarged plan view of a light-emitting unit;

FIGS. 9A and 9B are cross-sectional views of a light-emitting unit, FIG. 9A is a cross-sectional view taken along line IXA-IXA in FIG. 8, and FIG. 9B is a cross-sectional view taken along line IXB-IXB in FIG. 8;

FIG. 10 illustrates a light-emitting device that is a modification of the light-emitting device to which the present exemplary embodiment is applied;

FIG. 11 illustrates a light-emitting device that is a modification of the light-emitting device to which the present exemplary embodiment is applied;

FIG. 12 illustrates an equivalent circuit of a light-emitting device that is a modification of the light-emitting device to which the present exemplary embodiment is applied; and

FIG. 13 illustrates an equivalent circuit of a light-emitting device that is a modification of the light-emitting device to which the present exemplary embodiment is applied.

### DETAILED DESCRIPTION

An exemplary embodiment of the present disclosure is described in detail below with reference to the accompanying drawings.

Some measurement devices for measuring a three-dimensional shape (hereinafter referred to as a 3D shape) of an object to be measured measure a three-dimensional shape based on a Time of Flight (ToF) method using a flight time of light. According to the ToF method, a period from a timing of emission of light from a light-emitting device provided in a measurement device to a timing of reception of the light, by a three-dimensional sensor (hereinafter referred to as a 3D sensor) provided in the measurement device, reflected by the object to be measured is measured. Then, a 3D shape of the object to be measured is specified based on the measured period. A target of measurement of a 3D shape is referred to as an object to be measured. A three-dimensional shape may be referred to as a three-dimensional image. Measurement of a three-dimensional shape may be referred to as three-dimensional measurement, 3D measurement, or 3D sensing.

Such a measurement device is applied to recognition of an object to be measured from a measured 3D shape. For example, such a measurement device is mounted on a mobile information processing apparatus or the like and is used, for example, for recognition of a face of a user who tries to access the mobile information processing apparatus. That is, such a measurement device acquires a 3D shape of a face of a user who accesses the mobile information processing apparatus, determines whether or not the user has access permission, and permits the user to use the mobile information processing apparatus only in a case where the user is recognized as having access permission.

Furthermore, this measurement device is also applied to a case where a 3D shape of an object to be measured is continuously measured (e.g., Augmented Reality (AR)). In this case, a distance to the object to be measured does not matter.

Such a measurement device is applicable to an information processing apparatus, such as a personal computer (PC), other than a mobile information processing apparatus.

It is assumed here that an information processing apparatus is a mobile information processing apparatus as an example and that a user is authenticated by recognition of a face captured as a 3D shape.

### Information Processing Apparatus 1

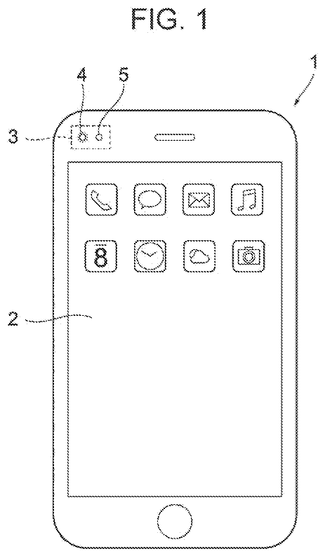

FIG. 1 illustrates an example of an information processing apparatus 1. As described above, the information processing apparatus 1 is a mobile information processing apparatus as an example.

The information processing apparatus 1 includes a user interface unit (hereinafter referred to as a UI unit) 2 and an optical device 3 that measures a 3D shape. The UI unit 2 is, for example, configured such that a display device that displays information for a user and an input device that receives an instruction for information processing given by a user's operation are integrated. The display device is, for example, a liquid crystal display or an organic EL display, and the input device is, for example, a touch panel.

The optical device 3 includes a light-emitting device 4 and a 3D sensor 5. The light-emitting device 4 radiates light toward an object to be measured (a face in this example). The 3D sensor 5 acquires light reflected back by the face. In this example, a 3D shape is measured based on the ToF method using a flight time of light. Then, the face is recognized based on the 3D shape. As described earlier, a 3D shape of an object to be measured other than a face may be measured. A measurement device that measures a 3D shape includes the light-emitting device 4 and the 3D sensor 5.

The information processing apparatus 1 is a computer including a CPU, a ROM, and a RAM. Examples of the ROM include a non-volatile rewritable memory, for example, a flash memory. A program or a constant number stored in the ROM is loaded into the RAM, and the CPU executes the program. In this way, the information processing apparatus 1 operates, and various kinds of information processing are executed.

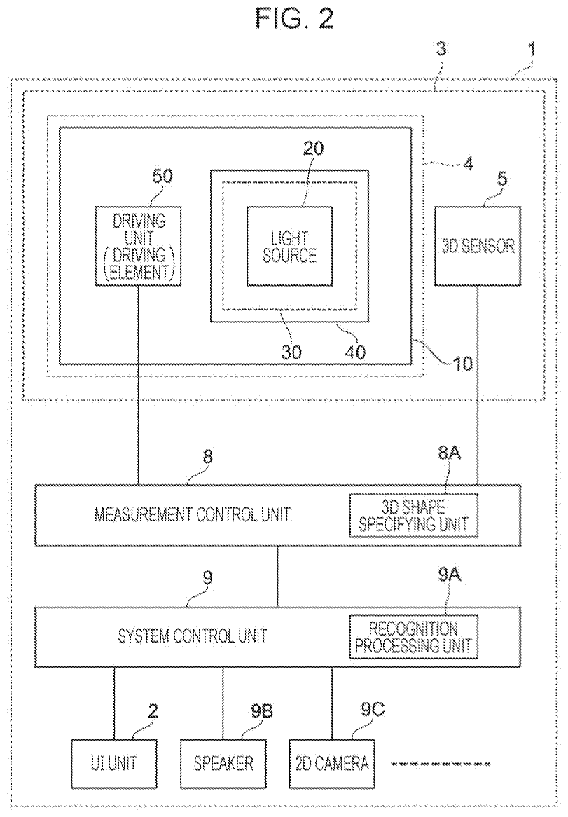

FIG. 2 is a block diagram for explaining a configuration of the information processing apparatus 1.

The information processing apparatus 1 includes the optical device 3, a measurement control unit 8, and a system control unit 9. The measurement control unit 8 measures a 3D shape by controlling the optical device 3. The measurement control unit 8 includes a 3D shape specifying unit 8A. The system control unit 9 controls the whole information processing apparatus 1 as a system. The system control unit 9 includes a recognition processing unit 9A. The system control unit 9 is connected to the UI unit 2, a speaker 9B, a two-dimensional camera (referred to as a 2D camera in FIG. 2) 9C, and the like.

The 3D shape specifying unit 8A included in the measurement control unit 8 specifies a 3D shape of an object to be measured by measuring a 3D shape based on light reflected by the object to be measured. The recognition processing unit 9A included in the system control unit 9 recognizes the object to be measured (a face in this example) based on the 3D shape specified by the 3D shape specifying unit 8A. Then, the recognition processing unit 9A included in the system control unit 9 distinguishes whether or not a user has access permission based on the recognized face.

The light-emitting device 4 included in the optical device 3 includes a wiring substrate 10, a light source 20, a light diffusion member 30, and a driving unit 50. The light source 20 and the driving unit 50 are disposed on the wiring substrate 10. The light source 20 and the driving unit 50 are connected by a wire provided in the wiring substrate 10. The driving unit 50 supplies a current for light emission to the light source 20. The light diffusion member 30 is provided on a path of light emitted by the light source 20 and causes light emitted by the light source 20 to be radiated in a desired direction. For example, the light diffusion member 30 is held by a holding unit 40 provided on the wiring substrate 10 and covers the light source 20. Note that the wiring substrate 10 may include a resistive element and a capacitive element for causing the light source 20 and the driving unit 50 to operate. The light source 20 may be provided on a heat releasing base member having a higher coefficient of thermal conductivity than the wiring substrate 10. Examples of the heat releasing base member include alumina (Al₂O₃) having a coefficient of thermal conductivity of 20 W/m·K to 30 W/m·K, silicon nitride (Si₃N₄) having a coefficient of thermal conductivity of approximately 85 W/m·K, and aluminum nitride (AlN) having a coefficient of thermal conductivity of 150 W/m·K to 250 W/m·K as compared with a coefficient of thermal conductivity of approximately 0.4 W/m·K of an insulating layer called FR-4 used for the wiring substrate 10. Although a case where the wiring substrate 10 is provided with a wire is described, the wiring substrate 10 may be a substrate that is provided with no wire. The wiring substrate 10 may be any substrate that holds members such as the light source 20 and the driving unit 50 in a manner such that the light source 20 and the driving unit 50 are connected to each other.

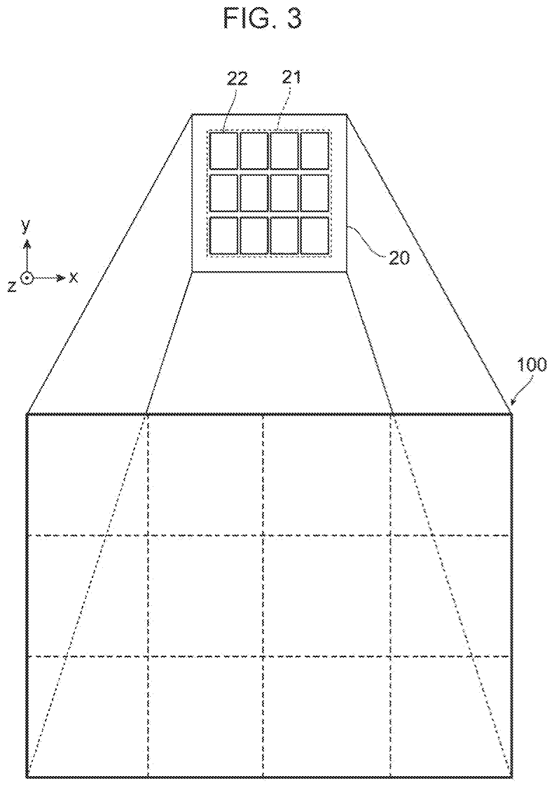

FIG. 3 is a perspective view for explaining a state where the light source 20 of the light-emitting device 4 irradiates an irradiation region 100 in a divided manner. FIG. 3 illustrates the light source 20 of the light-emitting device 4. In FIG. 3, the rightward direction, the upward direction, and a direction toward the irradiation region 100 in a portion where the light source 20 is provided on the paper on which FIG. 3 is drawn are an x direction, a y direction, and a z direction, respectively.

The light source 20 includes, for example, 12 light-emitting units 22. The 12 light-emitting units 22 are collectively referred to as a light output unit 21. The 12 light-emitting units 22 are arranged in a matrix of four light-emitting units 22 in the x direction and three light-emitting units 22 in the y direction. Each of the light-emitting units 22 may emit light individually or plural light-emitting units 22 may emit light concurrently. Furthermore, all of the light-emitting units 22 may emit light concurrently.

The irradiation region 100 is a range irradiated with light emitted by the light source 20 in order to measure a 3D shape of an object to be measured. The light-emitting units 22 are different in irradiation range. That is, the light source 20 irradiates the irradiation region 100 in a divided manner. Light emitted by the light-emitting units 22 passes the light diffusion member 30 (see FIG. 2), so that an irradiation direction and/or spread of light are set. Note that an optical member such as a diffractive optical element (DOE) that outputs light after changing a direction of incident light to a different direction or a transparent member such as a collecting lens, a microlens, or a protection cover may be provided instead of the light diffusion member 30.

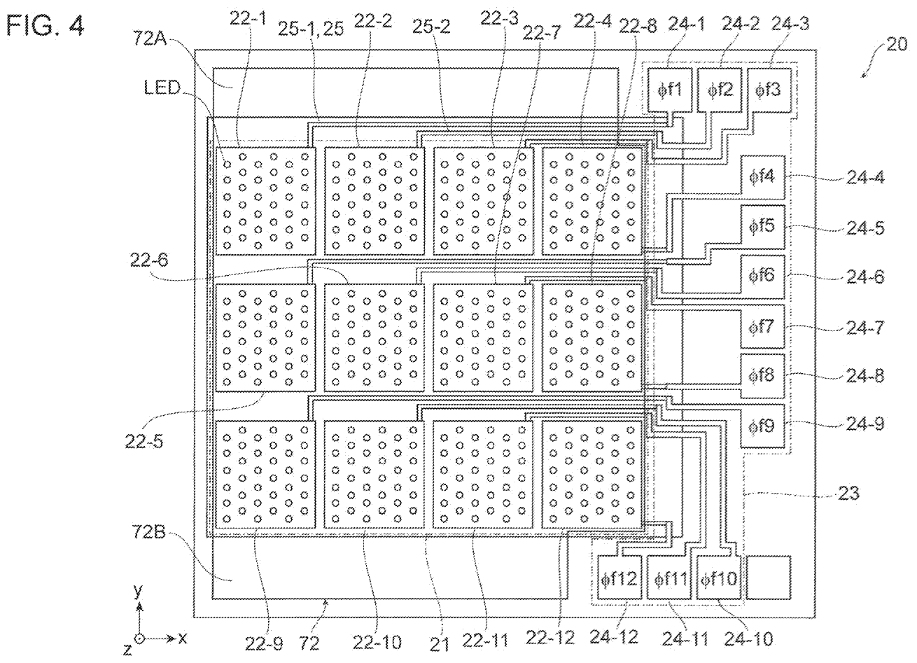

FIG. 4 is a view for explaining the light source 20 in the light-emitting device 4. The x direction, the y direction, and the z direction in FIG. 4 are similar to those in FIG. 3.

The light source 20 includes the light output unit 21 in which the plural light-emitting units 22 are arranged, a switching unit 23 that switches a light-emitting unit 22 that emits light, and wires 25 that connect the light-emitting units 22 and the switching unit 23.

The light output unit 21 includes the 12 light-emitting units 22 arranged in a matrix (four in the x direction and three in the y direction), as described above. The light-emitting units 22 are referred to as light-emitting units 22-1 to 22-12 to distinguish the light-emitting units 22. The circles illustrated on the light-emitting units 22 indicate light-emitting diodes LED, which are an example of light-emitting elements. That is, each of the light-emitting units 22 includes plural light-emitting diodes LED. Note that the light-emitting units 22 may include the same number of light-emitting elements or may include different numbers of light-emitting elements. Each of the light-emitting units 22 may include a single light-emitting element.

An electrode for light emission 72 is provided common to all of the light-emitting units 22 on the light output unit 21 (z direction side). The electrode for light emission 72 has, on ±y direction sides, pad units 72A and 72B to which a wire for supplying a current for light emission is connected. Note that only a frame of the electrode for light emission 72 is illustrated so that the light-emitting units 22 below the electrode for light emission 72 is visible.

The switching unit 23 includes signal terminals 24-1 to 24-12 that supply switching signals φf1 to φf12 to the light-emitting units 22-1 to 22-12, respectively. Note that in a case where the switching signals φf1 to φf12 are not distinguished, the switching signals φf1 to φf12 are referred to as switching signals φf, and in a case where the signal terminals 24-1 to 24-12 are not distinguished, the signal terminals 24-1 to 24-12 are referred to as signal terminals 24. The switching unit 23 is gathered on an x direction side of the light output unit 21 including the plural light-emitting units 22. The switching unit 23 may be configured such that the signal terminals 24 are aligned in a line on a y direction side. This makes a length in the x direction shorter than a case where the signal terminals 24 are not aligned in a line.

The light-emitting units 22 of the light output unit 21 and the signal terminals 24 of the switching unit 23 are connected by the wires 25, and the switching signals φf are supplied from the signal terminals 24. Specifically, the light-emitting unit 22-1 and the signal terminal 24-1 are connected by the wire 25-1, and the switching signal φf1 is supplied. The light-emitting unit 22-2 and the signal terminal 24-2 are connected by the wire 25-2, and the switching signal φf2 is supplied from the signal terminal 24-2. In FIG. 4, the wires 25-1 and 25-2 are given reference signs, and reference signs of the other wires 25-3 to 25-12 are omitted.

The wires 25 are provided along the light-emitting units 22 outside the light-emitting units 22. This allows light-emitting diodes LED to be provided in a higher density than a case where the wires 25 are provided inside the light-emitting units 22, that is, on surfaces of the light-emitting units 22. In FIG. 4, a region including the light output unit 21 and the switching unit 23 is longer in the x direction than in the y direction.

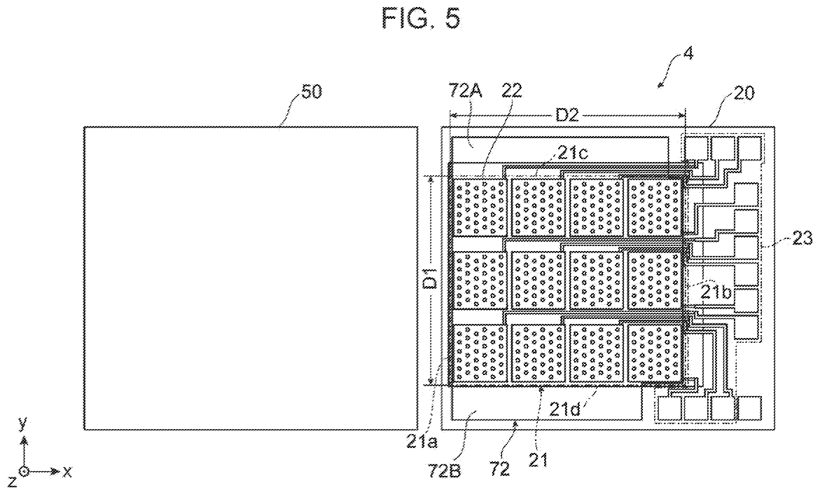

FIG. 5 is a view for explaining a way in which the light source 20 and the driving unit 50 in the light-emitting device 4 are disposed. The x direction, the y direction, and the z direction in FIG. 5 are similar to those in FIG. 4.

A −x direction side, a +x direction size, a +y direction side, and a −y direction side of the light output unit 21 including the plural light-emitting units 22 are referred to as an edge 21a, an edge 21b, an edge 21c, and an edge 21d, respectively. The edge 21a and the edge 21b face each other, and the edge 21c and the edge 21d connect the edge 21a and the edge 21b and face each other. That is, the plural light-emitting units 22 of the light output unit 21 are surrounded by the edges 21a, 21b, 21c, and 21d. The edge 21a has a length D1, and the edge 21c has a length D2. The length D1 is set shorter than the length D2 (D1<D2). The edge 21a is an example of a first edge, the edge 21b is an example of a second edge, the edge 21c is an example of a third edge, and the edge 21d is an example of a fourth edge.

As illustrated in FIG. 5, the switching unit 23 is disposed on a side opposite to a side where the driving unit 50 is disposed. That is, the driving unit 50 is provided adjacent to the light-emitting units 22 of the light output unit 21. That is, the driving unit 50 is provided on a side where the edge 21a of the light output unit 21 is located, and the switching unit 23 is provided on a side where the edge 21b of the light output unit 21 is located. That is, the driving unit 50 and the switching unit 23 are provided alongside edges that are opposed to each other. This makes a distance between the driving unit 50 and the light-emitting units 22 shorter than a case where the switching unit 23 is provided between the driving unit 50 and the light-emitting units 22. This reduces inductance between the driving unit 50 and the light-emitting units 22 in the light source 20 in the light-emitting device 4, thereby shortening a rise time of light pulse. Since the 3D sensor 5 is disposed at the position illustrated in FIG. 1, the 3D sensor 5 is provided on the switching unit 23 side. That is, the driving unit 50, the light-emitting units 22, the switching unit 23, and the 3D sensor 5 are arranged in this order.

The pad unit 72A of the electrode for light emission 72 is provided on a side where the edge 21c of the light output unit 21 including the light-emitting units 22 is located, and the pad unit 72B of the electrode for light emission 72 is provided on a side where the edge 21d of the light output unit 21 is located. That is, the pad units 72A and 72B are provided outside the light output unit 21 at positions different, relative to the light output unit 21, from the positions where the driving unit 50 and the switching unit 23 are provided. If the pad units 72A and 72B are provided at the position where the switching unit 23 or the driving unit 50 is provided, connection to the pad units 72A and 72B may be undesirably hindered by the switching unit 23 or the driving unit 50. That is, connection to the pad units 72A and 72B is easier than a case where the pad units 72A and 72B are provided at the position where the switching unit 23 or the driving unit 50 is provided. The pad units 72A and 72B are provided on the edge 21c and the edge 21d, respectively. Accordingly, a current is supplied from both sides of the electrode for light emission 72. This suppresses unevenness of supply of a current to the light-emitting units 22 as compared with a case where a pad unit is provided on either the edge 21c or the edge 21d.

That is, the driving unit 50, the switching unit 23, and the electrode for light emission 72 are provided alongside respective different edges of the light output unit 21. This can reduce a planar shape of the light-emitting device 4.

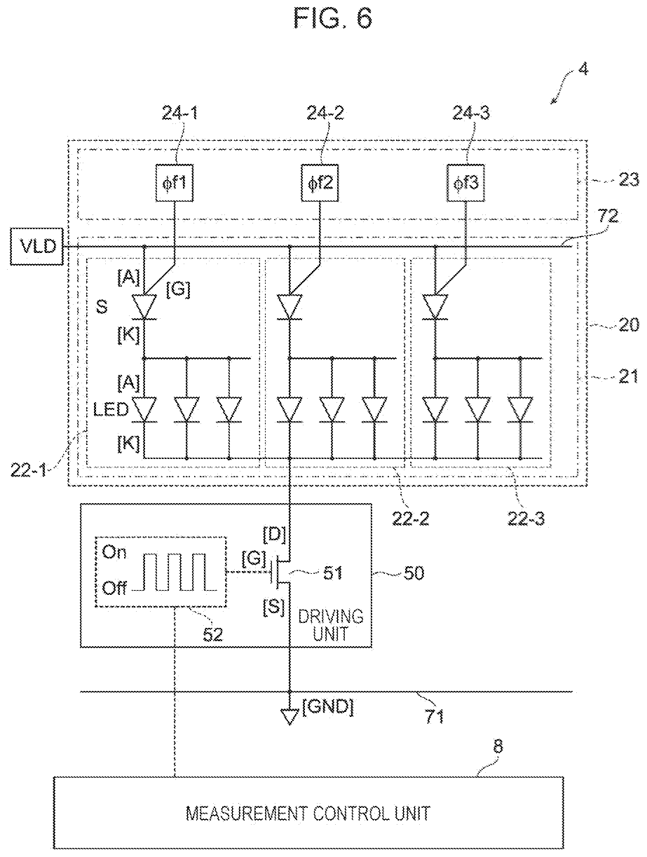

FIG. 6 illustrates an equivalent circuit of the light-emitting device 4 to which the present exemplary embodiment is applied. In FIG. 6, the light source 20 and the driving unit 50 in the light-emitting device 4 are illustrated. In FIG. 6, the measurement control unit 8 that controls the light-emitting device 4 is also illustrated.

As described earlier, the light source 20 includes the light output unit 21 and the switching unit 23 that switches the plural light-emitting units 22 in the light output unit 21. In FIG. 6, three light-emitting units 22 (the light-emitting units 22-1, 22-2, and 22-3) are illustrated. Each of the light-emitting units 22 includes plural light emitting diodes LED (see the light-emitting unit 22-1). Furthermore, each of the light-emitting units 22 includes a driving thyristor S connected to the plural light emitting diodes LED.

The light-emitting diodes LED are, for example, vertical cavity surface emitting lasers (VCSELs). In the following description, it is assumed that the light-emitting diodes LED are vertical cavity surface emitting lasers (VCSELs). The vertical cavity surface emitting lasers (VCSELs) are surface emitting laser elements that include a light-emitting layer, which is a light-emitting region, between a lower multilayer reflecting mirror and an upper multilayer reflecting mirror stacked on a substrate and emit laser light in a direction orthogonal to a surface. The vertical cavity surface emitting lasers (VCSELs) have a λ resonator structure. Note that the light-emitting elements may be other light-emitting devices such as laser diodes other than the vertical cavity surface emitting lasers (VCSELs). Hereinafter, the vertical cavity surface emitting lasers (VCSELs) are sometimes referred to as VCSELs.

The driving unit 50 includes an MOS transistor 51 as an example of a driving element and a signal generation circuit 52. Note that the driving element may be an insulated gate bipolar transistor (IGBT) or the like.

The plural light emitting diodes LED and the driving thyristor S are connected in series. That is, the plural light emitting diodes LED are connected in parallel, and anodes (“A”) of the light emitting diodes LED are connected to a cathode (“K”) of the driving thyristor S. Similarly, the cathodes (“K”) of the light emitting diodes LED are connected in parallel and are connected to a drain (“D”) of the MOS transistor 51 in the driving unit 50. A source (“S”) of the MOS transistor 51 is connected to a reference potential wire 71 that supplies a reference potential GND (0V).

An anode (“A”) of the driving thyristor S is connected to the electrode for light emission 72 to which a power supply potential VLD is supplied. A gate (“G”) of the driving thyristor S is connected to a corresponding one of the signal terminals 24 of the switching unit 23. That is, in the light-emitting unit 22-1, the gate (“G”) of the driving thyristor S is connected to the signal terminal 24-1, and the switching signal φf1 is supplied. The same applies to the other light-emitting units 22.

The signal generation circuit 52 of the driving unit 50 supplies an On signal (On) for turning the MOS transistor 51 on and an Off signal (Off) for turning the MOS transistor 51 off to the gate (“G”) of the MOS transistor 51.

A driving method of the light-emitting device 4 is low-side driving. The low-side driving is desirable for higher-speed driving of the light-emitting diodes LED. The low-side driving refers to a configuration in which a driving element such as the MOS transistor 51 is located on a downstream side of a current path relative to a driving target such as the light-emitting diodes LED.

Operation of the light-emitting device 4 is described below.

### Driving Thyristor S

The driving thyristor S is a semiconductor element having three terminals: the anode (“A”), the cathode (“K”), and the gate (“G”). As described later, the driving thyristor S is configured such that an n-cathode layer 85, a p-gate layer 86, an n-gate layer 87, and a p-anode layer 88 made of a material such as GaAs, AlGaAs, or AlAs are stacked. That is, the driving thyristor S has an npnp structure. The following describes, as an example, a case where a forward voltage (diffusion potential) Vd of a pn junction between a p-type semiconductor layer (the p-gate layer 86, the p-anode layer 88) and an n-type semiconductor layer (the n-cathode layer 85, the n-gate layer 87) is 1.5V.

The driving thyristor S has the gate (“G”) in the n-gate layer 87. First, it is assumed that the driving thyristor S is in an off state where no current is flowing although a voltage is applied between the anode (“A”) and the cathode (“K”) of the driving thyristor S. When a bias between the p-anode layer 88, which is the anode (“A”), and the n-gate layer 87, which is the gate (“G”), becomes a forward bias, the driving thyristor S shifts to an on state where a current flows. That is, in FIG. 6, when the voltage of the gate (“G”) becomes lower than the potential of the anode (“A”) by more than the forward voltage Vd, the driving thyristor S shifts from an off state to an on state. The voltage between the anode (“A”) and the cathode (“K”) becomes the forward voltage Vd. For example, in a case where the anode (“A”) is 5V, the driving thyristor S shifts from an off state to an on state when the gate (“G”) becomes less than 3.5V. In a case where the anode (“A”) is 10V, the driving thyristor S shifts from an off state to an on state when the gate (“G”) becomes less than 8.5V.

Note that the gate (“G”) is connected to a corresponding one of the signal terminals 24, and the switching signal φf is supplied to the signal terminal 24. That is, shift from an off state to an on state of the driving thyristor S is controlled by the switching signal φf.

### Light Emitting Diode LED

Each of the light-emitting diodes LED is a semiconductor element having two terminals: the anode (“A”) and the cathode (“K”). Accordingly, the light-emitting diode LED emits light when a voltage higher than the forward voltage Vd is applied between the anode (“A”) and the cathode (“K”) and a current that enables light emission flows.

### Operation of Light-Emitting Units 22

As illustrated in FIG. 6, the light-emitting units 22 are configured such that the driving thyristor S and the light emitting diodes LED are connected in series. The power supply potential VLD is applied to the electrode for light emission 72 to which the anode (“A”) of the driving thyristor S is connected. The cathode (“K”) of the light emitting diode LED is connected to the drain (“D”) of the MOS transistor 51 of the driving unit 50. The reference potential GND (0V) is supplied to the source (“S”) of the MOS transistor 51 of the driving unit 50. Note that the reference potential GND is a grounding potential.

It is assumed here that when an On signal is supplied from the signal generation circuit 52 to the gate (“G”) of the MOS transistor 51, the MOS transistor 51 shifts to an on state. As a result, the cathodes (“K”) of the light emitting diodes LED of the light-emitting units 22 become 0V. Accordingly, the power supply potential VLD is applied to the light-emitting units 22.

It is assumed that the power supply potential VLD is 5V. Furthermore, it is assumed that the switching signal φf is 5V and the driving thyristor S is in an off state. The switching signal φf shifts to less than 3.5V, which is lower than the power supply potential VLD of the anode (“A”) of the driving thyristor S by more than the forward voltage Vd. As a result, the driving thyristor S shifts from an off state to an on state. A current flows from the driving thyristor S to the light emitting diodes LED. The cathode (“K”) of the driving thyristor S becomes 3.5V. Accordingly, a voltage between the anode (“A”) and the cathode (“K”) of each of the light emitting diodes LED becomes equal to or higher than the forward voltage Vd, and the light emitting diodes LED emit light.

It is assumed that the power supply potential VLD is 10V. It is assumed that the switching signal φf is 10V and the driving thyristor S is in an off state. The switching signal φf shifts to less than 8.5V, which is lower than the power supply potential VLD, which is the potential of the anode (“A”) of the driving thyristor S, by more than the forward voltage Vd. As a result, the driving thyristor S shifts from an off state to an on state. A current flows from the driving thyristor S to the light emitting diodes LED. The cathode (“K”) of the driving thyristor S becomes 8.5V. Accordingly, a voltage between the anode (“A”) and the cathode (“K”) of each of the light emitting diodes LED becomes equal to or higher than the forward voltage Vd, and the light emitting diodes LED emit light.

As described above, the driving thyristor S that is in an off state maintains the off state in a case where a voltage applied to the gate (“G”), that is, the switching signal φf is equal to or higher than a value obtained by subtracting the forward voltage Vd from the power supply potential VLD. The driving thyristor S shifts from an off state to an on state when the switching signal φf becomes less than a value obtained by subtracting the forward voltage Vd from the power supply potential VLD.

When an Off signal is input from the signal generation circuit 52 to the gate (“G”) of the MOS transistor 51, the MOS transistor 51 shifts from an on state to an off state. As a result, a current is no longer flows through the light-emitting units 22, and the light emitting diodes LED shift from an on state to an off state. Note that the driving thyristor S that is in an on state does not shift to an off state even when the gate (“G”) becomes equal to or higher than a value obtained by subtracting the forward voltage Vd from the power supply potential VLD.

### Timing Diagram of Light-Emitting Device 4

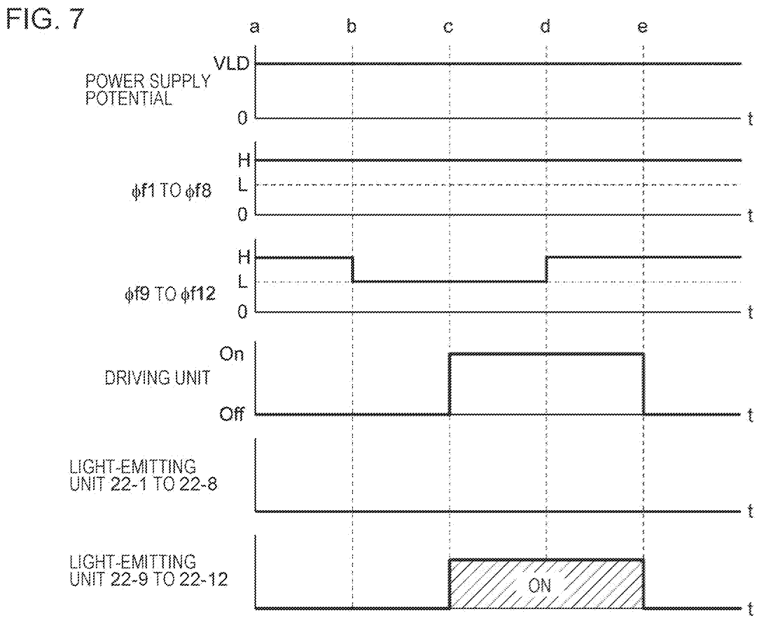

FIG. 7 is a timing diagram for explaining operation of the light-emitting device 4. The horizontal axis represents a time t, which elapses in an order of times a to e. FIG. 7 illustrates the power supply potential VLD, the switching signals φf1 to φf8, the switching signals φf9 to φf12, a signal of the signal generation circuit 52 of the driving unit 50, states of the light-emitting units 22-1 to 22-8, and states of the light-emitting units 22-9 to 22-12 from up to down. The switching signals φf1 to φf12 are signals switched between an H level and an L level. Note that the H level is equal to or higher than a value obtained by subtracting the forward voltage Vd from the power supply voltage VLD, and the L level is less than the value obtained by subtracting the forward voltage Vd from the power supply voltage VLD. It is, for example, assumed that the switching signals φf1 to φf8 are maintained at the same potential, and the switching signals φf9 to φf12 are concurrently switched. Note that each of the switching signals φf1 to φf12 may be independently switched or plural switching signals may be switched concurrently as described above. Alternatively, all of the switching signals φf1 to φf12 may be switched concurrently.

At the time a, the light-emitting units 22-1 to 22-12 are in an off state. The switching signals φf1 to φf12 are at the H level. The signal generation circuit 52 of the driving unit 50 is supplying an Off signal to the MOS transistor 51. Accordingly, all of the driving thyristors S are in an off state, and all of the light-emitting diodes LED are in a non-light-emission state.

At the time b, the switching signals φf9 to φf12 shift from the H level to the L level. As a result, the gates (“G”) of the driving thyristors S of the light-emitting units 22-9 to 22-12 become the L level, so that the driving thyristors S become capable of shifting from an off state to an on state. However, the driving thyristors S cannot shift to an on state since the MOS transistor 51 of the driving unit 50 is in an off state.

At the time c, the signal generation circuit 52 of the driving unit 50 supplies an On signal to the MOS transistor 51. Accordingly, the power supply potential VLD is applied to the serial connection between the driving thyristors S and the light-emitting diodes LED of the light-emitting units 22-9 to 22-12. As a result, the driving thyristors S shift from an off state to an on state, and the light-emitting diodes LED start light emission (turn on).

At the time d, the switching signals φf9 to φf12 shift from the L level to the H level. However, the driving thyristors S of the light-emitting units 22-9 to 22-12 do not shift to an off state, and the light-emitting diodes LED continue light emission.

At the time e, the signal generation circuit 52 of the driving unit 50 supplies an Off signal to the MOS transistor 51. As a result, a current no longer flows through the serial connection between the driving thyristors S and the light-emitting diodes LED of the light-emitting units 22-9 to 22-12, and the light-emitting diodes LED stop light emission (turn off).

As described above, the light-emitting device 4 is controlled. Note that a timing at which the switching signals φf9 to φf12 shift from the H level to the L level at the time b and a timing at which the signal generation circuit 52 of the driving unit 50 supplies an On signal to the MOS transistor 51 at the time c may be exchanged. In this case, the light-emitting diodes LED start light emission at the timing at which the switching signals φf9 to φf12 shift from the H level to the L level. Furthermore, a timing at which the switching signals φf9 to φf12 shift from the L level to the H level at the time d and a timing at which the signal generation circuit 52 of the driving unit 50 supplies an Off signal to the MOS transistor 51 at the time e may be exchanged.

### Structure of Light-Emitting Units 22

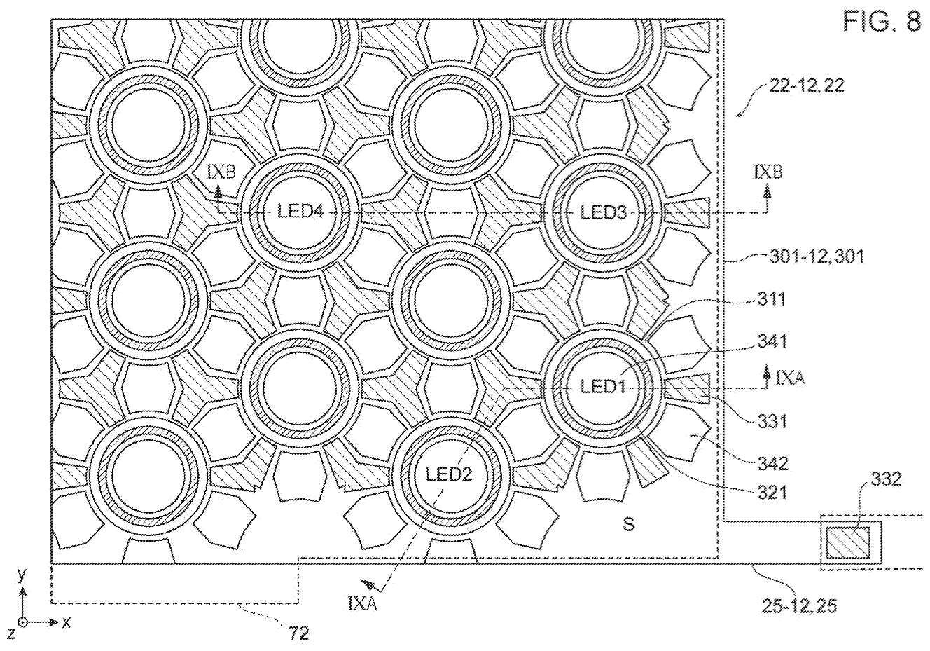

The light source 20 is made of a semiconductor material that can emit light. For example, the light source 20 is made of a GaAs-based compound semiconductor. The light source 20 is a semiconductor layer multilayer body in which plural GaAs-based compound semiconductor layers are stacked on an n-type GaAs substrate 80, as illustrated in a cross-sectional view described later (see FIG. 8, which will be described later). The light source 20 is configured such that the semiconductor layer multilayer body is separated into plural island shapes. Note that regions remaining in island shapes are referred to as islands. Etching the semiconductor layer multilayer body into island shapes to provide separate elements is referred to as mesa etching.

The light-emitting units 22 are provided in islands 301 that are separated from each other. Note that the islands 301 corresponding to the light-emitting units 22-1, 22-2, . . . are referred to as islands 301-1, 301-2, . . . , respectively.

FIG. 8 is an enlarged plan view of the light-emitting unit 22. FIG. 8 a partially enlarged view of the light-emitting unit 22-12 (the island 301-12) in the light source 20 illustrated in FIG. 4. In the following description, the light-emitting unit 22-12 is referred to as the light-emitting unit 22, and the island 301-12 is referred to as the island 301. The x direction, the y direction, and the z direction in FIG. 8 are similar to those in FIG. 4.

FIG. 8 illustrates plural light-emitting diodes LED. In FIG. 8, four light-emitting diodes are given reference signs LED1 to LED4, respectively. First, a planar structure of the light-emitting unit 22 is described by focusing on the light-emitting diode LED1 located in a lower right portion of the paper on which FIG. 8 is drawn. Note that the light-emitting diode LED1 is referred to as the light-emitting diode LED without distinction. The same applies hereinafter.

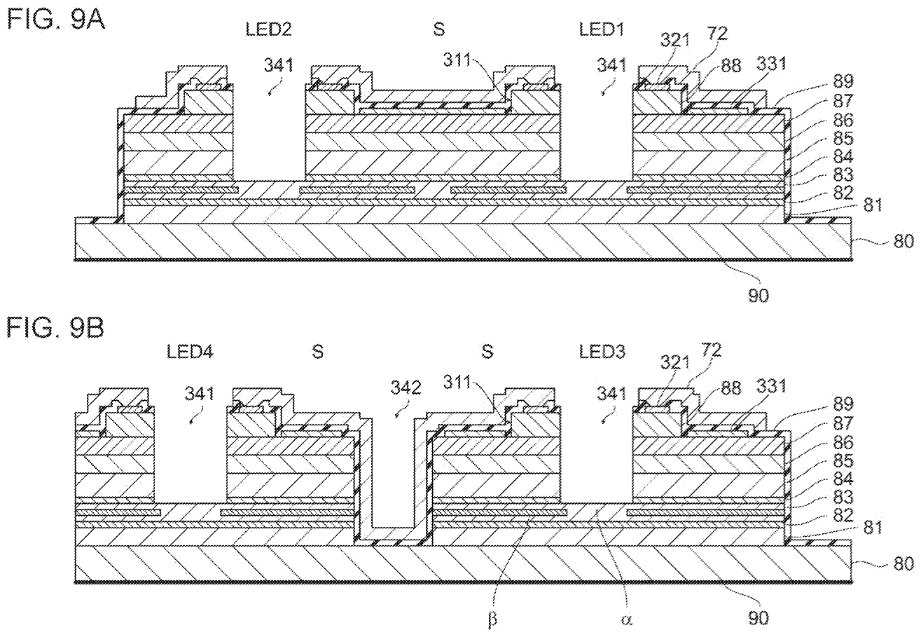

A central circular portion of the light-emitting diode LED is a light emission opening 341 of the light-emitting diode LED. A region 311 (see FIG. 9, which will be described later) of the p-anode layer 88 of the driving thyristor S is provided so as to surround the light emission opening 341. A p-ohmic electrode 321 is provided on the region 311. Furthermore, six holes (trenches) 342 and six gate electrodes 331 are provided outside the p-ohmic electrode 321. The gate electrodes 331 are provided on the n-gate layer 87, which will be described later. Note that the gate electrodes 331 includes a gate electrode 331 that is continuous with a gate electrode 331 of an adjacent light-emitting diode LED.

The n-gate layer 87 is drawn out to the switching unit 23 side, and a gate electrode 332 connected to the signal terminal 24 is provided at an end thereof. The gate electrode 332 is connected to the signal terminal 24-12 of the switching unit 23 (see FIG. 4). Note that a part of the n-gate layer 87 that is drawn out to the switching unit 23 side is the wire 25 (corresponding to the wire 25-12 in this case).

The electrode for light emission 72 is provided so as to cover the light-emitting unit 22 except for the light emission opening 341. The electrode for light emission 72 is connected to the p-ohmic electrode 321 provided on the region 311 through a through-hole provided in an insulating layer 89 (see FIGS. 9A and 9B, which will be described later). In FIG. 8, the electrode for light emission 72 is indicated by the broken line.

FIGS. 9A and 9B are cross-sectional views of the light-emitting unit 22. FIG. 9A is a cross-sectional view taken along line IXA-IXA in FIG. 8, and FIG. 9B is a cross-sectional view taken along line IXB-IXB in FIG. 8. FIG. 9A is a cross-sectional view of a portion where the two light emitting diodes LED1 and LED2 that are adjacent with the gate electrode 331 interposed therebetween are provided. FIG. 9B is a cross-sectional view of a portion where the two light emitting diodes LED3 and LED4 with the hole 342 interposed therebetween are provided.

As illustrated in FIG. 9A, the light-emitting unit 22 is configured such that an n-type cathode layer (hereinafter referred to as an n-cathode layer; the same applies hereinafter) 81, a light emission layer 82, and a p-type anode layer (p-anode layer) 83 that constitute the light-emitting diode LED are stacked on the n-type GaAs substrate 80. That is, the light-emitting diode LED is configured such that the n-cathode layer 81 serving as a cathode, the light emission layer 82 serving as a light emission layer, and the p-anode layer 83 serving as an anode are stacked.

Next, a tunnel junction layer 84 is stacked on the p-anode layer 83.

The n-type cathode layer (n-cathode layer) 85, the p-type gate layer (p-gate layer) 86, the n-type gate layer (n-gate layer) 87, and the p-type anode layer (p-anode layer) 88 that constitute the driving thyristor S are stacked on the tunnel junction layer 84. That is, the driving thyristor S is configured such that the n-cathode layer 85 serving as a cathode, the p-gate layer 86 serving as a p-gate, the n-gate layer 87 serving as an n-gate, and the p-anode layer 88 serving as an anode are stacked.

The light-emitting diode LED is configured such that the p-anode layer 88, the n-gate layer 87, the p-gate layer 86, the n-cathode layer 85, and the tunnel junction layer 84 of the driving thyristor S stacked on an upper side are removed by etching to expose the p-anode layer 83. That is, light is emitted from the exposed p-anode layer 83. The exposed p-anode layer 83 is the light emission opening 341.

The driving thyristor S is constituted by the n-cathode layer 85, the p-gate layer 86, the n-gate layer 87, and the p-anode layer 88 that remain around the light emission opening 341 of the light-emitting diode LED. The tunnel junction layer 84 and the p-anode layer 83, the light emission layer 82, and the n-cathode layer 81 that constitute the light-emitting diode LED are provided on a substrate 80 side of the driving thyristor S. That is, the light-emitting diode LED and the driving thyristor S are stacked with the tunnel junction layer 84 interposed therebetween and are connected in series.

The tunnel junction layer 84 is provided between the p-anode layer 83 of the light-emitting diode LED and the n-cathode layer 85 of the driving thyristor S. That is, without the tunnel junction layer 84, the p-anode layer 83 of the light-emitting diode LED and the n-cathode layer 85 of the driving thyristor S are in an inverse bias state, and therefore a current is hard to flow from the n-cathode layer 85 of the driving thyristor S to the p-anode layer 83 of the light-emitting diode LED. The tunnel junction layer 84 is a junction of a P⁺⁺ layer doped with a high concentration of p-type impurities on the p-anode layer 83 side of the light-emitting diode LED and an n⁺⁺ layer doped with a high concentration of n-type impurities on the n-cathode layer 85 side of the driving thyristor S. Since a width of a depletion region in the tunnel junction layer 84 is narrow, tunneling of electrons from an n⁺⁺ layer side conduction band to a p⁺⁺ layer side valence band occurs in an inverse bias state. Accordingly, electrons are easy to flow from the n-cathode layer 85 of the driving thyristor S to the p-anode layer 83 of the light-emitting diode LED.

The p-ohmic electrode 321 that makes ohmic contact with the p-anode layer 88 is provided on the p-anode layer 88. The p-ohmic electrode 321 is connected to the electrode for light emission 72 through a through-hole provided in the insulating layer 89.

Furthermore, the gate electrode 331 that makes ohmic contact with the n-gate layer 87 exposed by etching a part of the p-anode layer 88 is provided. The gate electrode 331 reduces resistance of the exposed n-gate layer 87.

Note that the electrode for light emission 72 and the gate electrode 331 are insulated with the insulating layer 89 interposed therebetween.

As illustrated in FIG. 9A, the n-cathode layer 81, the light emission layer 82, the p-anode layer 83, the tunnel junction layer 84, the n-cathode layer 85, the p-gate layer 86, the n-gate layer 87, and the p-anode layer 88 are continuous between the light emission opening 341 of the light-emitting diode LED1 and the light emission opening 341 of the light-emitting diode LED2 that are adjacent to each other with the gate electrode 331 interposed therebetween.

As illustrated in FIG. 9B, the light emission opening 341 of the light-emitting diode LED3 and the light emission opening 341 of the light-emitting diode LED4 are adjacent to each other with the hole 342 interposed therebetween. The hole 342 is provided by removing the p-anode layer 88, the n-gate layer 87, the p-gate layer 86, the n-cathode layer 85, the tunnel junction layer 84, the p-anode layer 83, the light emission layer 82, and the n-cathode layer 81. A current constriction layer contained in the p-anode layer 83 is oxidized through the hole 342, so that a portion close to the hole 342 is turned into a current blocking portion β where a current is hard to flow. Meanwhile, a portion far from the hole 342 remains without being oxidized. That is, the portion that is not oxidized becomes a current passage portion α where a current flows. Plural holes 342 are provided around the light emission opening 341 so as to surround the light emission opening 341. Accordingly, the current passage portion α has a shape close to a circle. The light emission opening 341 is provided corresponding to the current passage portion α. With this configuration, although the n-cathode layer 81, the p-anode layer 83, and the light emission layer 82 are provided continuously for the light-emitting diodes LED of the light-emitting unit 22, each of the light-emitting diodes LED emits light in the light emission opening 341.

Meanwhile, as illustrated in FIG. 9A, the n-cathode layer 85, the p-gate layer 86, the n-gate layer 87, and the p-anode layer 88 that constitute the driving thyristor S are continuous between the light-emitting diodes LED. Accordingly, the driving thyristors S operate for each light-emitting unit 22. That is, as illustrated in FIG. 6, in each of the light-emitting units 22, a single driving thyristor S is provided so the plural light emitting diodes LED.

Between the light-emitting units 22, that is, between the islands 301, the p-anode layer 88, the n-gate layer 87, the p-gate layer 86, the n-cathode layer 85, the tunnel junction layer 84, the p-anode layer 83, the light emission layer 82, and the n-cathode layer 81 are removed, as in the right end of FIGS. 8A and 8B. That is, the p-anode layer 83, the light emission layer 82, and the n-cathode layer 81 that constitute the light-emitting diode LED and the p-anode layer 88, the n-gate layer 87, the p-gate layer 86, and the n-cathode layer 85 that constitute the driving thyristor S are not continuous between the islands 301. Therefore, light emission is individually controlled for each of the light-emitting units 22.

### Configuration of Semiconductor Layer Multilayer Body

The n-cathode layer 81, the light emission layer 82, the p-anode layer 83, the tunnel junction layer 84, the n-cathode layer 85, the p-gate layer 86, the n-gate layer 87, and the p-anode layer 88 stacked on the substrate 80 is the semiconductor layer multilayer body. The n-cathode layer 81, the light emission layer 82, and the p-anode layer 83 are semiconductor layers that constitute the light emitting diode LED, and the n-cathode layer 85, the p-gate layer 86, the n-gate layer 87, and the p-anode layer 88 are semiconductor layers that constitute the driving thyristor S.

These are described below in order.

### Substrate 80

Although an example in which the substrate 80 is made of n-type GaAs is described, the substrate 80 may be made of p-type GaAs or may be made of intrinsic (i) GaAs doped with no impurity. Alternatively, the substrate 80 may be a semiconductor substrate made of InP, GaN, InAs, or other III-V group or II-VI materials, sapphire, Si, Ge, or the like. In a case where a different substrate is used, a material that substantially matches (including a strain structure, a strain relaxation layer, and metamorphic growth) a lattice constant of the substrate is used as a material stacked monolithically on the substrate. For example, InAs, InAsSb, GaInAsSb, or the like is used on an InAs substrate, InP, InGaAsP, or the like is used on an InP substrate, GaN, AlGaN, or InGaN is used on a GaN substrate or a sapphire substrate, and Si, SiGe, GaP, or the like is used on a Si substrate. However, in a case where the substrate 80 is electrically insulating, it is necessary to separately provide an electrode that supplies a potential to the n-cathode layer 81. In a case where the semiconductor layer multilayer body excluding the substrate 80 is attached onto another support substrate, matching with a lattice constant of the support substrate is unnecessary.

### Semiconductor Layers Constituting Light-Emitting Diode LED

It is assumed here that the light-emitting diode LED is a VCSEL.

The n-cathode layer 81 constitutes an n-type lower distributed bragg reflector (DBR) in which AlGaAs layers different in Al composition are alternately stacked. The light emission layer 82 is configured as an active region including a quantum well layer sandwiched between an upper spacer layer and a lower spacer layer. The p-anode layer 83 is configured as an upper distributed bragg reflector in which AlGaAs layers different in Al composition are alternately stacked. Hereinafter, the distributed bragg reflector is referred to as a DBR. Light output of a single VCSEL is 4 mW to 8 mW, which is higher than that of other laser diodes.

The n-type lower DBR that constitutes the n-cathode layer 81 is a multilayer body constituted by pairs of an Al_{0.9}Ga_{0.1}As layer and a GaAs layer. The layers of the lower DBR each have a thickness of λ/4nᵣ (λ is an oscillation wavelength, and nᵣ is a refractive index of a medium) and are alternately stacked so that 40 pairs of the layers are stacked. Silicon (Si), which is an n-type impurity, is doped as a carrier. A carrier concentration is, for example, 3×10¹⁸ cm⁻³.

The lower spacer layer that constitutes the light emission layer 82 is an undoped Al_{0.6}Ga_{0.4}As layer, the quantum well layer is an undoped InGaAs quantum well layer and an undoped GaAs barrier layer, and the upper spacer layer is an undoped Al_{0.6}Ga_{0.4}As layer.

The p-type upper DBR that constitutes the p-anode layer 83 is a multilayer body constituted by pairs of a p-type Al_{0.9}Ga_{0.1}As layer and a GaAs layer. The layers of the upper DBR each have a thickness of ×/4nᵣ and are alternately stacked so that 29 pairs are stacked. Carbon (C), which is a p-type impurity, is doped as a carrier. A carrier concentration is, for example, 3×10¹⁸ cm⁻³. A p-type AlAs current constriction layer is provided in a bottommost layer or in an inner portion of the upper DBR 208.

The p-type AlAs is higher in oxidation speed than AlGaAs, and an oxidized region is oxidized from a side surface of the hole 342 toward an inner side. Al is oxidized to form Al₂O₃. This increases electric resistance, thereby forming the current blocking portion β. Note that the current constriction layer may be any material having a high Al impurity concentration such as p-type AlGaAsGaAs instead of AlAs as long as Al is oxidized to form Al₂O₃. The current blocking portion β may be formed by implanting hydrogen ions (H⁺) in a semiconductor layer such as AlGaAs (H⁺ ion implantation).

### Tunnel Junction Layer 84

The tunnel junction layer 84 is a junction of a p⁺⁺ layer doped with a high concentration of p-type impurities and an n⁺⁺ layer doped with a high concentration of n-type impurities. The n⁺⁺ layer and the p⁺⁺ layer have, for example, a high concentration of impurities of 1×10²⁰/cm³. Note that an impurity concentration of a normal junction is 10¹⁷/cm³ order to 10¹⁸/cm³ order. A combination of the p⁺⁺ layer and the n⁺⁺ layer (hereinafter referred to as a p⁺⁺ layer/n⁺⁺ layer) is, for example, p⁺⁺GaAs/n⁺⁺GaInP, p⁺⁺AlGaAs/n⁺⁺GaInP, p⁺⁺GaAs/n⁺⁺GaAs, p⁺⁺AlGaAs/n⁺⁺AlGaAs, p⁺⁺InGaAs/n⁺⁺InGaAs, p⁺⁺GaInAsP/n⁺⁺GaInAsP, or p⁺⁺GaAsSb/n⁺⁺GaAsSb. Note that the p⁺⁺ layer or the n⁺⁺ layer in a combination may be exchanged with one in another combination.

### Semiconductor Layers Constituting Driving Thyristor S

The n-cathode layer 85 is, for example, n-type Al_{0.9}GaAs having an impurity concentration of 1×10¹⁸/cm³. The Al composition may be changed within a range of 0 to 1.

The p-gate layer 86 is, for example, p-type Al_{0.9}GaAs having an impurity concentration of 1×10¹⁷/cm³. The Al composition may be changed within a range of 0 to 1.

The n-gate layer 87 is, for example, n-type Al_{0.9}GaAs having an impurity concentration of 1×10¹⁷/cm³. The Al composition may be changed within a range of 0 to 1.

The p-anode layer 88 is, for example, p-type Al_{0.9}GaAs having an impurity concentration of 1×10¹⁸/cm³. The Al composition may be changed within a range of 0 to 1.

### Method for Producing Light Source 20

The light source 20 is produced as follows.

The n-cathode layer 81, the light emission layer 82, the p-anode layer 83, the tunnel junction layer 84, the n-cathode layer 85, the p-gate layer 86, the n-gate layer 87, and the p-anode layer 88 are stacked in order on the substrate 80. Next, the p-anode layer 88, the n-gate layer 87, the p-gate layer 86, the n-cathode layer 85, the tunnel junction layer 84, the p-anode layer 83, the light emission layer 82, and the n-cathode layer 81 are etched to form portions separating the light-emitting units 22 and the holes 342.

Then, the current constriction layer in the p-anode layer 83 is oxidized from the side surface of the hole 342 in oxidizing atmosphere to form the current blocking portion β.

Furthermore, a part of the p-anode layer 88 is etched to expose a surface of the n-gate layer 87. Then, the p-ohmic electrode 321 is formed on the p-anode layer 88, and the gate electrode 331 that makes ohmic contact with the n-gate layer 87 is formed on the n-gate layer 87. The p-ohmic electrode 321 is, for example, made of a material such as Zn-containing Au (AuZn) that makes ohmic contact with p-type AlGaAs. The gate electrode 331 is, for example, made of a material such as Ge-containing Au (AuGe) that makes ohmic contact with n-type AlGaAs.

Next, the insulating layer 89 is formed on a front face. Then, the insulating layer 89, the p-anode layer 88, the n-gate layer 87, the p-gate layer 86, the n-cathode layer 85, and the tunnel junction layer 84 are etched to form the light emission opening 341. The insulating layer 89 is, for example, SiO₂ or SiN.

Then, a through-hole is formed in a portion of the insulating layer 89 where the p-ohmic electrode 321 is provided, and the electrode for light emission 72 is formed. Note that the signal terminals 24 of the switching unit 23 and a wire that connects the signal terminals 24 and the n-gate layer 87 are formed concurrently with the electrode for light emission 72.

Note that the order of the steps for producing the light source 20 may be changed. For example, the light emission opening 341 may be formed before formation of the insulating layer 89. In this case, the light emission opening 341 is covered with the insulating layer 89 and is thus protected. In this case, a material that allows transmission of light from the light emitting diodes LED is used for the insulating layer 89.

As described above, in a case where the light emitting diodes LED and the driving thyristor S are stacked, light emission of the light emitting diodes LED is controlled by supplying the switching signal φf to the driving thyristor S. That is, light emission of the light emitting diodes LED is controlled more easily than a case where the light emitting diodes LED and the driving thyristor S are not stacked.

### Modification of Light-Emitting Device 4

In the light-emitting device 4 to which the present exemplary embodiment is applied illustrated in FIG. 5, the light-emitting units 22 are arranged in a matrix in the light output unit 21 of the light source 20. However, the light-emitting units 22 need not necessarily arranged in a matrix.

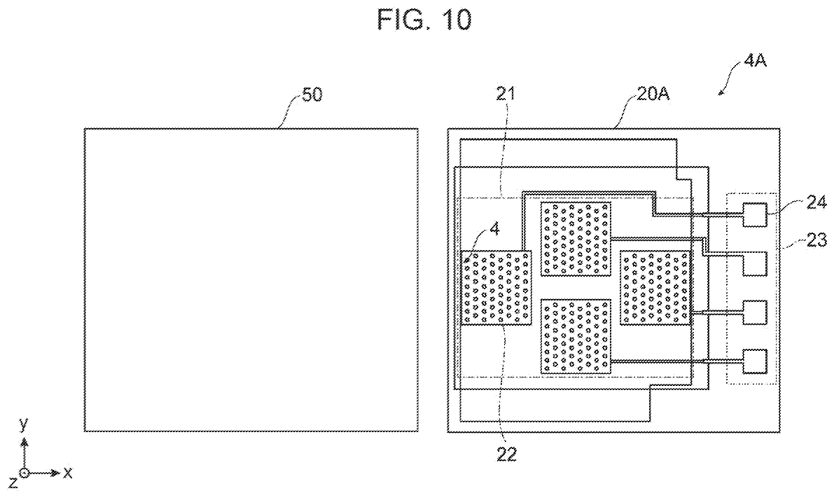

FIG. 10 illustrates a light-emitting device 4A, which is a modification of the light-emitting device 4 to which the present exemplary embodiment is applied. A light source 20A of the light-emitting device 4A is different from the light source 20 of the light-emitting device 4. The light-emitting device 4A is similar to the light-emitting device 4 except for this. Parts of the light source 20A that are identical to those of the light source 20 are given identical reference signs.

The light source 20A includes four light-emitting units 22. The four light-emitting units 22 are not arranged in a matrix. The plural light-emitting units 22 may be arranged in a manner other than a matrix as in this case. Note that the switching unit 23 is disposed on a side opposite to a side where the driving unit 50 is provided. This makes a distance between the driving unit 50 and the light-emitting units 22 shorter than a case where the switching unit 23 is provided between the driving unit 50 and the light-emitting units 22. This reduces inductance between the driving unit 50 and the light-emitting units 22 of the light source 20 in the light-emitting device 4A, thereby shortening a rise time of light pulse.

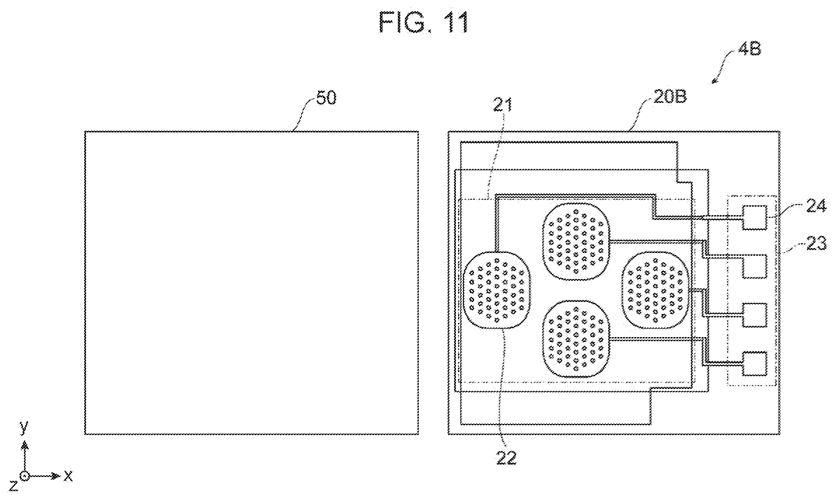

FIG. 11 illustrates a light-emitting device 4B, which is a modification of the light-emitting device 4 to which the present exemplary embodiment is applied. A light source 20B of the light-emitting device 4B is different from the light source 20 of the light-emitting device 4. The light-emitting device 4B is similar to the light-emitting device 4 except for this. Parts of the light source 20B that are identical to those of the light source 20 are given identical reference signs.

The light-emitting units 22 (see FIG. 4) of the light source 20 of the light-emitting device 4 to which the present exemplary embodiment is applied and the light-emitting units 22 (see FIG. 10) of the light source 20A of the light-emitting device 4A have a quadrangular planar shape. Meanwhile, the planar shape of the light-emitting units 22 of the light source 20B of the light-emitting device 4B illustrated in FIG. 11 is a quadrangle with rounded corners. The planar shape of the light-emitting units 22 may be a shape, such as a circle, an ellipse, or a polygonal shape, other than a quadrangle. Note that the switching unit 23 is disposed on a side opposite to a side where the driving unit 50 is provided. This makes a distance between the driving unit 50 and the light-emitting units 22 shorter than a case where the switching unit 23 is provided between the driving unit 50 and the light-emitting units 22. This reduces inductance between the driving unit 50 and the light-emitting units 22 of the light source 20 in the light-emitting device 4B, thereby shortening a rise time of light pulse.

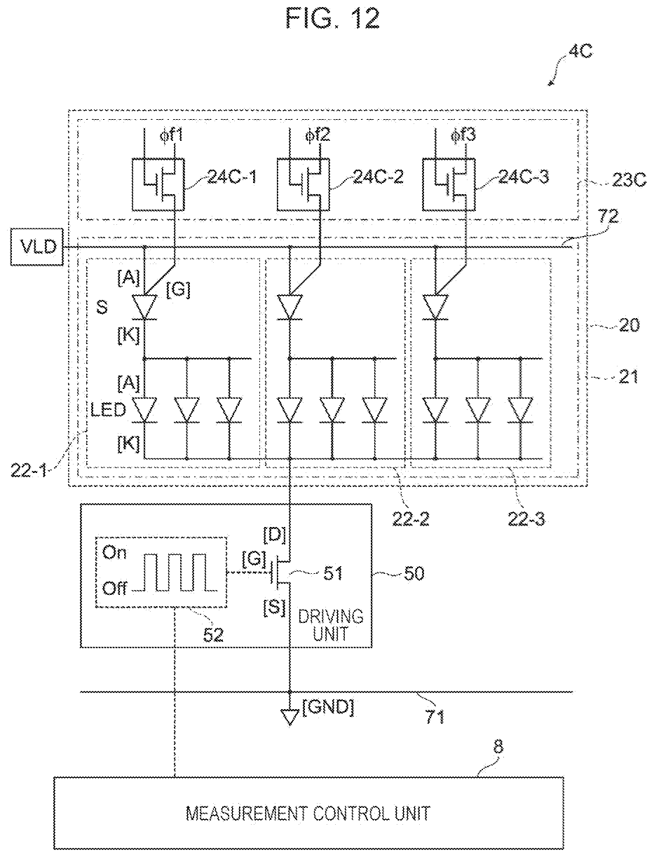

FIG. 12 illustrates an equivalent circuit of a light-emitting device 4C, which is a modification of the light-emitting device 4 to which the present exemplary embodiment is applied. A switching unit 23C of the light-emitting device 4C is different from the switching unit 23 of the light-emitting device 4. The light-emitting device 4C is similar to the light-emitting device 4 except for this.

The switching unit 23 of the light-emitting device 4 is constituted by the signal terminals 24 provided corresponding to the light-emitting units 22. The switching unit 23C of the light-emitting device 4C is constituted by switching elements 24C. The switching signals φf are supplied to the driving thyristors S through the switching elements 24C. Note that the switching elements 24C corresponding to the light-emitting units 22-1, 22-2, and 22-3 are referred to as switching elements 24C-1, 24C-2, and 24C-3 in FIG. 12.

The switching unit 23C may be constituted by the switching elements 24C as in this case.

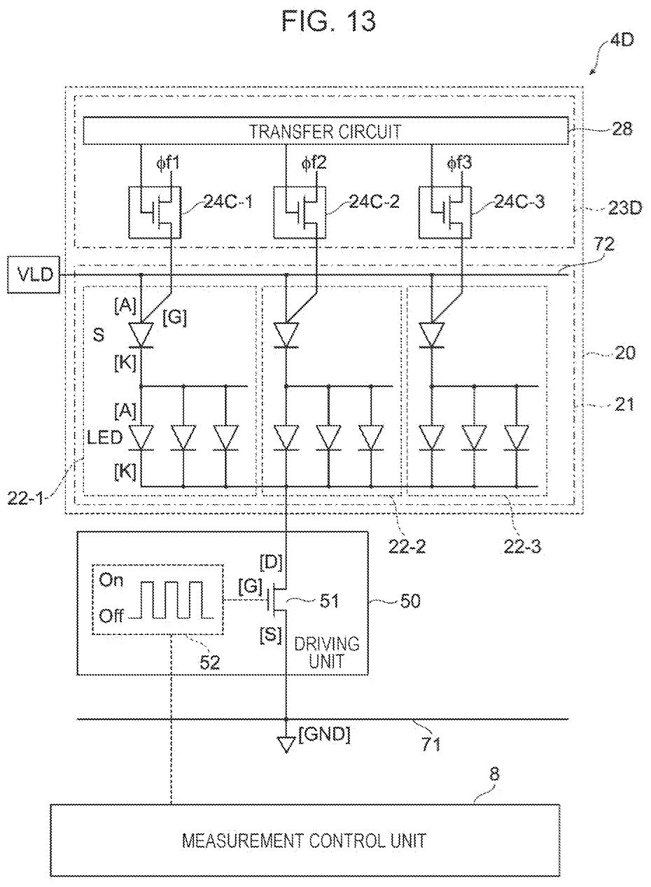

FIG. 13 illustrates an equivalent circuit of a light-emitting device 4D, which is a modification of the light-emitting device 4 to which the present exemplary embodiment is applied. A switching unit 23D of the light-emitting device 4D is different from the switching unit 23 of the light-emitting device 4. The light-emitting device 4D is similar to the light-emitting device 4 except for this.

The switching unit 23D includes a transfer circuit 28 that sequentially transfers an on state of the switching element 24C in addition to the switching elements 24C of the light-emitting device 4C. That is, the transfer circuit 28 causes the switching element 24C-2 to shift from an off state to an on state after the switching element 24C-1 shifts from an off state to an on state and shifts to an off state again. In this way, the transfer circuit 28 sequentially transfers an on state. This causes the plural light-emitting units 22 to emit light sequentially. That is, light emission of the light-emitting units 22 is controlled by supplying a start signal for starting light emission to the transfer circuit 28 without the need to individually control light emission of the light-emitting units 22. Such a transfer circuit 28 is, for example, a shift register.

In the present exemplary embodiment, the light emitting diodes LED, which are an example of light-emitting elements, are provided on the substrate 80, and the driving thyristor S is stacked on the light emitting diodes LED. The driving thyristor S may be provided on the substrate 80, and the light emitting diodes LED may be stacked on the driving thyristor S.

Although the n-type substrate 80 is used in the present exemplary embodiment, the light source 20 having an opposite polarity may be provided by using a p-type substrate. In this case, the light-emitting diodes LED may be provided on the substrate, and the driving thyristor S may be stacked on the light emitting diodes LED. Alternatively, the driving thyristor S may be provided on the substrate 80, and the light emitting diodes LED may be stacked on the driving thyristor S.

In the present exemplary embodiment, the light-emitting units 22 are configured so that light-emitting elements (the light-emitting diodes LED in the present exemplary embodiment) of the same light-emitting unit 22 are adjacent to each other. This makes the configuration of the light-emitting units 22 easy. However, the light-emitting elements need not be gathered, and light-emitting elements connected to the same signal terminal 24 of the switching unit 23 may be regarded as a single light-emitting unit 22.

Although an example in which the light-emitting device 4 is used together with the 3D sensor 5 in the present exemplary embodiment, this is not restrictive. The present exemplary embodiment may be applied to a light-emitting device used for optical transmission. In this case, the light-emitting device 4 may be combined with an optical transmission path and light switched by a switching unit may be introduced into the same optical transmission path or may be introduced into different transmission paths.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

What is claimed is:

1. A light-emitting device comprising:
a plurality of light-emitting units;
a driving unit that drives the plurality of light-emitting units by supplying a current to the plurality of light-emitting units; and
a switching unit that is provided on a side opposite to a side where the driving unit is provided relative to the plurality of light-emitting units and switches light emission of the plurality of light-emitting units.

2. The light-emitting device according to claim 1, further comprising an electrode for light emission that supplies a current to the light-emitting units,
wherein the electrode for light emission has a pad unit that is located outside the plurality of light-emitting units at a position different from positions where the driving unit and the switching unit are provided relative to the plurality of light-emitting units.

3. A light-emitting device comprising:
a plurality of light-emitting units;
a driving unit that drives the light-emitting units by supplying a current to the light-emitting units;
a switching unit that is provided on a side opposite to a side where the driving unit is provided relative to the plurality of light-emitting units and switches light emission of the plurality of light-emitting units; and
an electrode for light emission that supplies a current to the plurality of light-emitting units,
wherein:
the plurality of light-emitting units have a first edge and a second edge that face each other and a third edge and a fourth edge that connect the first edge and the second edge and face each other; and
the driving unit, the switching unit, and the electrode for light emission are provided alongside respective different edges.

4. The light-emitting device according to claim 3, wherein:
the driving unit and the switching unit are provided alongside the first edge and the second edge that face each other, respectively.

5. The light-emitting device according to claim 4, wherein:
the electrode for light emission has a pad unit both alongside the third edge and alongside the fourth edge.

6. The light-emitting device according to claim 1, further comprising wires that connect the respective plurality of light-emitting units to the switching unit,
wherein the wires are provided along the light-emitting units outside the light-emitting units.

7. The light-emitting device according to claim 1, wherein:
the switching unit includes a switching element.

8. The light-emitting device according to claim 7, wherein:
an on state of the switching element provided for each of the light-emitting units is sequentially transferred.

9. The light-emitting device according to claim 1, wherein:
the light-emitting units each includes a light emitting diode and a thyristor that is stacked on the light emitting diode and causes the light emitting diode to emit light when the thyristor shifts to an on state.

10. The light-emitting device according to claim 9, wherein:
the light emitting diode is a vertical cavity surface emitting laser.

11. A measurement device comprising:
the light-emitting device according to claim 1; and
a three-dimensional sensor that receives light emitted from the light-emitting device and reflected by an objected to be measured.
